(19) United States
(12) Patent Application Publication
(10) Pub. No.: US 2017/0345650 A1
(43) Pub. Date: Nov. 30, 2017

(54) Fabrication of M-plane Gallium Nitride

(71) Applicant: NATIONAL SUN YAT-SEN UNIVERSITY, Kaohsiung (TW)

(72) Inventors: I-Kai Lo, Kaohsiung (TW); Shuo-Ting You, Kaohsiung (TW); Jenn-Kai Tsai, Kaohsiung (TW)

(21) Appl. No.: 15/241,810

(22) Filed: Aug. 19, 2016

(30) Foreign Application Priority Data
May 31, 2016 (TW) 105117061

(51) Int. Cl. H01L 21/02

(52) U.S. Cl. CPC H01L 21/02389; H01L 21/02554; H01L 21/02647

(57) ABSTRACT

The present disclosure provides a fabrication of M-plane gallium nitride which is able to grow M-plane gallium nitride without the need of expensive substrates, such as LiAlO₂, LiGaO₂ or SiC. The fabrication of M-plane gallium nitride includes preparing a zinc oxide hexagonal prism having a growth face, and growing a gallium nitride layer on the growth face of the zinc oxide hexagonal prism. The growth face is an M-plane perpendicular to a direction of gravity.

### CROSS REFERENCE TO RELATED APPLICATIONS

The application claims the benefit of Taiwan application serial No. 105117061, filed on May 31, 2016, and the subject matter of which is incorporated herein by reference.

### BACKGROUND OF THE INVENTION

### 1. Field of the Invention

The present invention generally relates to a fabrication of gallium nitride and, more particularly, to a fabrication of M-plane gallium nitride.

### 2. Description of the Related Art

c-plane gallium nitride is widely used in the light emitting diode. However, due to quantum confined Stark effect, c-plane gallium nitride is provided with reduced luminous efficiency. Replacing c-plane gallium nitride with M-plane gallium nitride may overcome the above problem, thus improving luminous efficiency. A conventional fabrication of M-plane gallium nitride uses LiAlO₂, LiGaO₂ or SiC as a substrate for growing M-plane gallium nitride thereon. However, production of these substrates is complicated with high cost, resulting in high production cost of M-plane gallium nitride.

In light of the above, such a conventional fabrication of M-plane gallium nitride still needs improvement.

### SUMMARY OF THE INVENTION

It is therefore the objective of this invention to provide a fabrication of M-plane gallium nitride which is able to grow M-plane gallium nitride without the need of expensive substrates, such as LiAlO₂, LiGaO₂ or SiC.

The present disclosure provides a fabrication of M-plane gallium nitride, including: preparing a zinc oxide hexagonal prism having a growth face, and growing a gallium nitride layer on the growth face of the zinc oxide hexagonal prism. The growth face is an M-plane perpendicular to a direction of gravity.

The fabrication of M-plane gallium nitride in the present disclosure can grow M-plane gallium nitride without the need of the expensive substrates such as LiAlO₂, LiGaO₂ or SiC. The fabrication of M-plane gallium nitride is provided with simple steps and low cost, thus reducing the production cost of the gallium nitride layer.

In a form shown, the zinc oxide hexagonal prism has a height of 1-3 μm and a diameter of 1-2 μm. As such, the growth face is provided with a fine quality, thus assuring the quality of the fabricated gallium nitride layer.

In the form shown, the gallium nitride layer is grown by plasma-assisted molecular beam epitaxy. The gallium nitride layer is grown at 500-600° C., or at 550° C. The gallium nitride layer is grown with an N/Ga flux ratio of 40-60, or with an N/Ga flux ratio 53. As such, lattice defect can be prevented, thus improving illuminating efficiency of the gallium nitride.

In the form shown, preparing the zinc oxide hexagonal prism includes preparing a base plate and growing the zinc oxide hexagonal prism on a surface of the base plate by hydrothermal reaction. The base plate is a Si(100) base plate. A reaction solution used in the hydrothermal reaction includes zinc nitrate hexahydrate and hexamethylenetetramine. As such, the zinc oxide hexagonal prism can be provided with high quality and low production cost.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is a flow chart of a fabrication of M-plane gallium nitride according to the present disclosure.

FIG. 2 is a ball stick model at an interface between zinc oxide and gallium nitride.

FIG. 3a is an XRD result of zinc oxide hexagonal prisms.

FIG. 3b is a SEM image of the zinc oxide hexagonal prisms.

FIG. 3c is an enlarged SEM image of one of the zinc oxide hexagonal prisms.

FIG. 4a is a SEM image of a gallium nitride layer.

FIG. 4b is an enlarged SEM image of the gallium nitride layer.

FIG. 5a is a TEM image of the zinc oxide hexagonal prism and the gallium nitride layer.

FIG. 5b is a SAD pattern of the gallium nitride layer.

FIG. 5c is a SAD pattern of the interface between the gallium nitride layer and the zinc oxide hexagonal prism.

FIG. 5d is a SAD pattern of the zinc oxide hexagonal prism.

FIG. 6 is a polarization-dependent PL spectra of the gallium nitride layer and the zinc oxide hexagonal prism.

In the various figures of the drawings, the same numerals designate the same or similar parts. Furthermore, when the terms “first”, “second”, “third”, “fourth”, “inner”, “outer”, “top”, “bottom”, “front”, “rear” and similar terms are used hereinafter, it should be understood that these terms have reference only to the structure shown in the drawings as it would appear to a person viewing the drawings, and are utilized only to facilitate describing the invention.

### DETAILED DESCRIPTION OF THE INVENTION

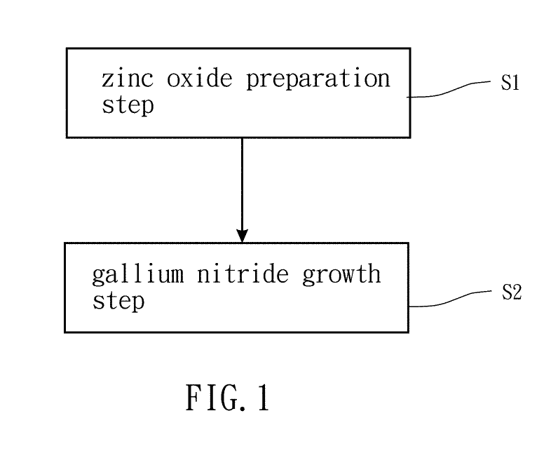

With reference to FIG. 1, a fabrication of M-plane gallium nitride according to the present disclosure may include a zinc oxide preparation step S1 and a gallium nitride growth step S2. The zinc oxide preparation step S1 my include preparing a zinc oxide hexagonal prism having a growth face, with the growth face being an M-plane perpendicular to a direction of gravity. The gallium nitride growth step S2 may include growing a gallium nitride layer on the growth face of the zinc oxide hexagonal prism.

The term “M-plane gallium nitride” used hereinafter in the specification refers to gallium nitride with a growth direction of [101̅0]. Specifically, the gallium nitride layer can grow on the growth face in a manner of M-plane stacking, such that the gallium nitride possesses M-plane characteristics.

The preparation of the zinc oxide hexagonal prism is not limited in the present disclosure. For instance, the zinc oxide hexagonal prism can be prepared by hydrothermal method on a surface of a base plate. The size of the zinc oxide hexagonal prism is preferably micrometer-scale, e.g. a height of said prism can be 1-3 μm, and a diameter (i.e. maximal length of the base face) of said prism can be 1-2 μm. As such, the growth face is provided with a fine quality, thus assuring the quality of the fabricated gallium nitride layer. In the present embodiment, on a surface of a Si(100) base plate, zinc nitrate hexahydrate and hexamethylenetetramine are used as reacting agents to conduct hydrothermal reaction at 70-100° C. for 10-20 hours, so as to grow the zinc oxide hexagonal prism on the Si(100) base plate.

The zinc oxide hexagonal prism is adapted for providing the growth face on which the gallium nitride layer grows. Specifically, the zinc oxide hexagonal prism has two base faces and six side faces, with each side face being M-plane. The zinc oxide hexagonal prism lays down with one of its M-plane perpendicular to the direction of gravity to serve as the growth face. In the present embodiment, the zinc oxide hexagonal prism has one of its M-plane adheres to the surface of the base plate, with an opposite one of its M-plane serving as the growth surface.

Before growing the gallium nitride, a pretreatment can be conducted to remove water and organic pollutions of the zinc oxide hexagonal prism, and to anneal the zinc oxide hexagonal prism. Specifically, in the present embodiment, the zinc oxide hexagonal prism (with the base plate) is dried at 180° C. under a vacuum of 10⁻⁷-10⁻⁸ torr. Organic pollutions of the zinc oxide hexagonal prism are removed at 550° C. under a vacuum of 10⁻⁹ torr. Finally, the zinc oxide hexagonal prism is annealed at 600-650° C. under a vacuum of 10⁻¹⁰ torr, providing an appropriate environment for growing the gallium nitride layer.

The gallium nitride layer can be grown by magnetron sputtering, atomic layer deposition, pulse laser deposition, and etc. Or, the gallium nitride layer can be grown by molecular beam epitaxy under a low-temperature environment. In the present embodiment, the gallium nitride layer is grown by plasma-assisted molecular beam epitaxy at 500-600° C. under a low N/Ga ratio (vapor pressure of N/vapor pressure of Ga) environment. For instance, the N/Ga flux ratio can be of 40-60, preferably set at 53; the growth time can be 30 min to 3 hr, preferably set at 1 hr, for producing the gallium nitride layer with less lattice defects. After growing the gallium nitride layer, the gallium nitride layer can be lifted off from the zinc oxide hexagonal prism by laser lift-off process. During the process of plasma-assisted molecular beam epitaxy, a high environmental temperature may cause dissociation of zinc oxide which reacts with nitrogen or gallium, resulting in stacking fault of the gallium nitride layer.

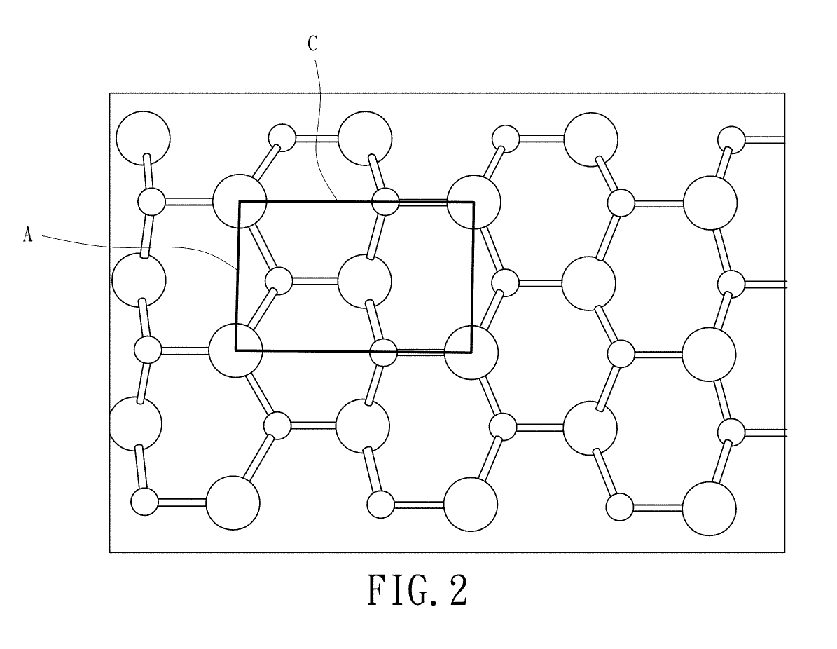

It is noteworthy that the lattice parameters of zinc oxide are a=3.25 Å and c=5.2 Å, which are very close to that of gallium nitride (3.20 Å and 5.18 Å), and the lattice-mismatch level of zinc oxide and gallium nitride is quite low (lattice-mismatches of [112̅0]_{ZnO}//[112̅0]_{GaN} and [0002]_{ZnO}//[0002]_{GaN} are 1.86% and 0.6%, respectively). Hence, with references to FIG. 2, in the a-axis direction A, a_{ZnO}≈a_{GaN}; and in the c-axis direction C, c_{ZnO}≈c_{GaN}. Accordingly, zinc oxide can be an appropriate substrate for growing M-plane gallium oxide thereon. Moreover, when growing the gallium nitride layer, the nitrogen source and the gallium source descend in the gravity direction to grow gallium nitride. Therefore, the growth face of the zinc oxide hexagonal prism must be perpendicular to the direction of gravity, such that the nitrogen and gallium sources can be deposited on the growth face to grow the gallium nitride layer upwardly from the M-plane of the zinc oxide hexagonal prism, forming M-plane gallium nitride. In contrast, if the zinc oxide hexagonal prism stands with one of its base faces adhering to the base plate and with its M-planes parallel to the gravity direction, only a small part of the nitrogen and gallium source can adhere on the M-plane of the zinc oxide hexagonal prism for growing M-plane gallium nitride. Thus, most of the nitrogen and gallium sources are deposited on the surface of the base plate instead of the M-plane. Gallium nitride which is not M-plane characterized may thus grow on the surface of the base plate and may adversely affect the growth of the gallium nitride layer growing on the growth face of the zinc oxide hexagonal prism.

For proving the ability of the fabrication of M-plane gallium nitride to grow gallium nitride layer which is M-plane, the following experiments are carried out.

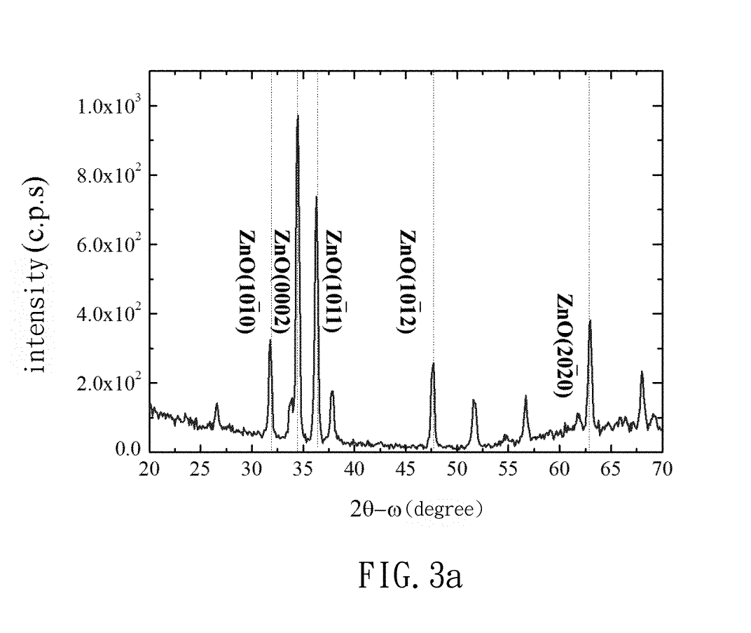

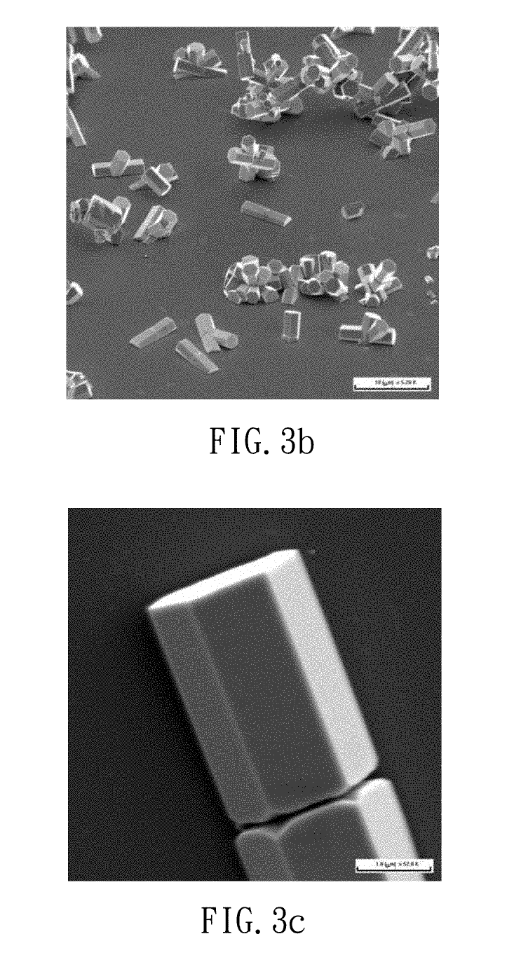

In this experiment, the zinc oxide hexagonal prism is grown on a Si(100) base plate by hydrothermal method at 90° C. for 60 min, with the reaction solution including 0.15 M zinc nitrate hexahydrate and 0.03 M hexamethylenetetramine. The zinc oxide hexagonal prism obtained is analyzed: the XRD result is shown in FIG. 3a, and the SEM images are shown in FIGS. 3b and 3c. These results show that the zinc oxide hexagonal prism having smooth M-plane can be prepared by hydrothermal method. Such a smooth M-plane can be adapted for the gallium nitride layer to grow thereon.

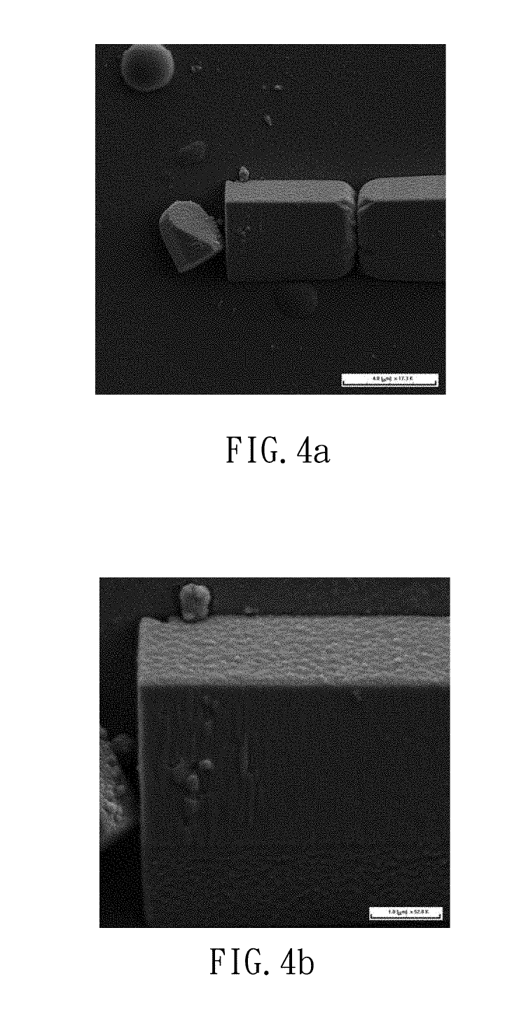

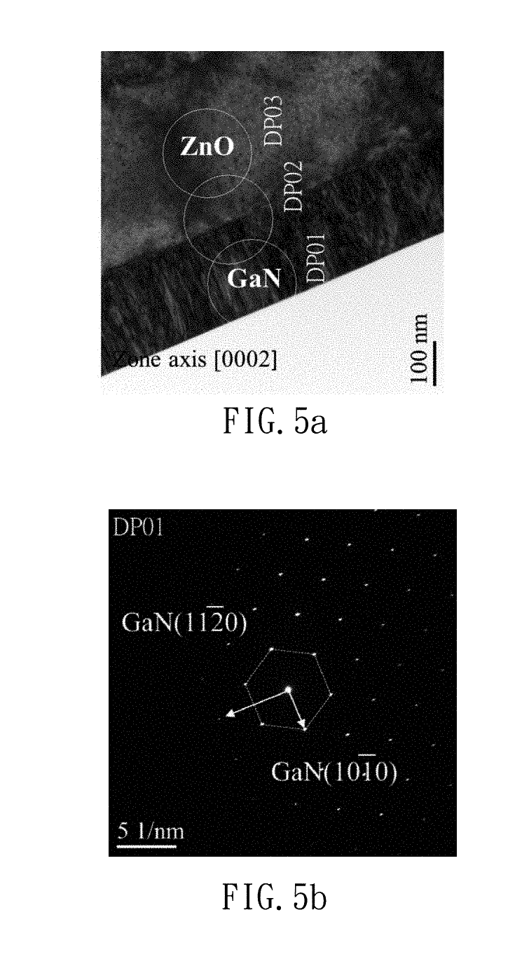

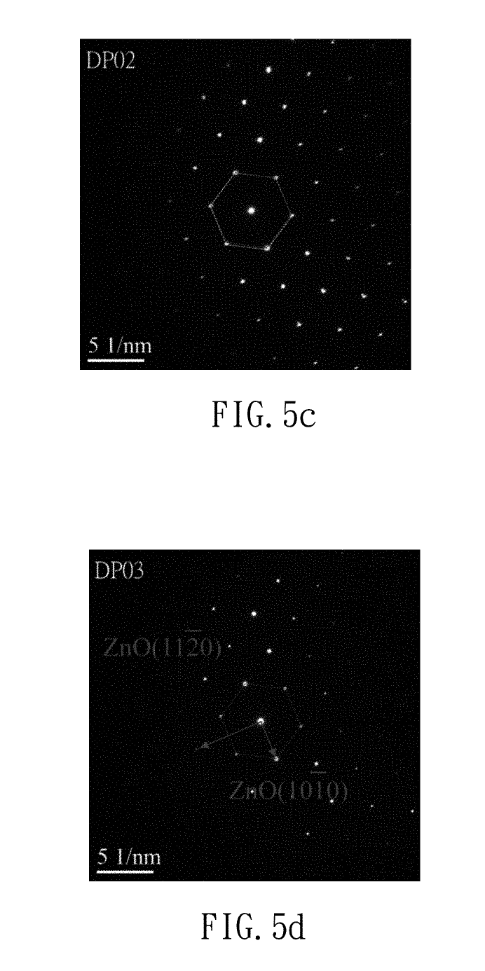

Next, the gallium nitride layer is grown on the growth face of the zinc oxide hexagonal prism by plasma-assisted molecular beam epitaxy at 550° C. for 60 min, with an N/Ga flux ratio of 53. The SEM images of the gallium nitride layer obtained are shown in FIGS. 4a and 4b. The zinc oxide hexagonal prism with M-plane gallium nitride is further analyzed by TEM and SAD, and the results are shown in FIGS. 5a-5d. FIG. 5a shows the cross sectional TEM image along [101̅0] direction; FIGS. 5b-5d are the SAD patterns taken at location DP01, DP02 and DP03 indicated in FIG. 5a. With references to FIG. 5b, the gallium nitride layer shows wurtzite structure with a growth direction of [101̅0]. With references to FIG. 5d, the zinc oxide hexagonal prism shows M-plane wurtzite structure. With references to FIG. 5c, the SAD patterns of the gallium nitride layer and the zinc oxide hexagonal prism overlap at location DP02, indicating the diffraction spots of GaN(112̅0)//ZnO(112̅0), thus proving that the gallium nitride layer is gown with [101̅0] direction parallel to ZnO[101̅0].

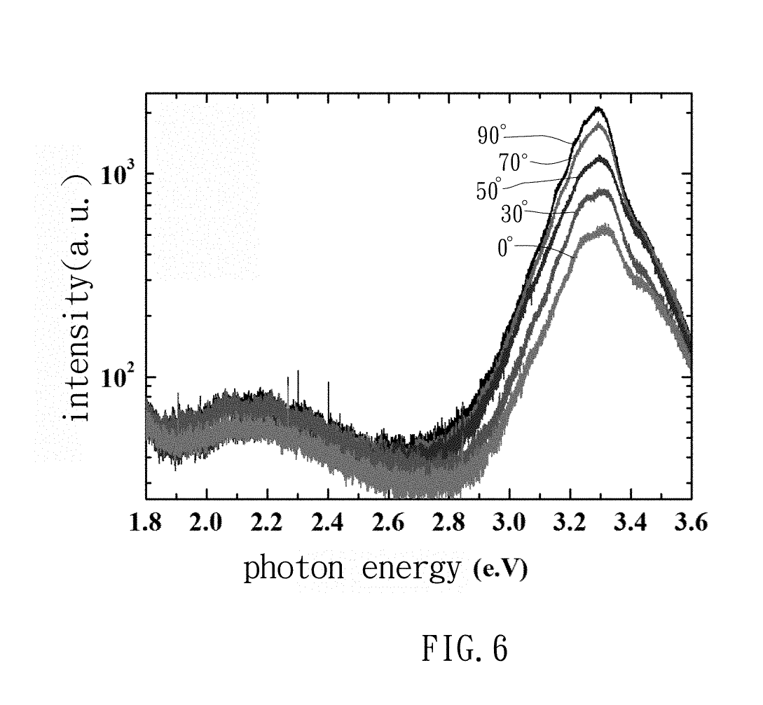

Furthermore, the zinc oxide hexagonal prism and M-plane gallium nitride are analyzed by polarization-dependent photoluminescence under room temperature, and the result is shown in FIG. 6. In this polarization-dependent PL spectra, φ=0° is defined parallel to c-axis. The intensity of PL spectra increased from φ=0° (E//c) to φ=90° (E⊥c), indicating the characteristic of nonpolar plane GaN and ZnO, which also proves that the gallium nitride layer is M-plane.

According to the above, by using the zinc oxide hexagonal prism as a substrate, the fabrication of M-plane gallium nitride in the present disclosure can grow M-plane gallium nitride without the need of the expensive substrates such as LiAlO₂, LiGaO₂ or SiC. The fabrication of M-plane gallium nitride is provided with simple steps and low cost, thus reducing the production cost of the gallium nitride layer.

Moreover, in the fabrication of M-plane gallium nitride of the present disclosure, the gallium nitride layer is grown on the growth surface of the zinc oxide hexagonal prism. Since the growth surface is an M-plane perpendicular to the direction of gravity, the gallium nitride layer can certainly form M-plane gallium nitride with less lattice defects, thus improving luminous efficiency of the gallium nitride layer.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A fabrication of M-plane gallium nitride, comprising:
preparing a zinc oxide hexagonal prism having a growth face, wherein the growth face is an M-plane perpendicular to a direction of gravity; and
growing a gallium nitride layer on the growth face of the zinc oxide hexagonal prism.

2. The fabrication of M-plane gallium nitride as claimed in claim 1, wherein the zinc oxide hexagonal prism has a height of 1-3 μm and a diameter of 1-2 μm.

3. The fabrication of M-plane gallium nitride as claimed in claim 1, wherein the gallium nitride layer is grown by plasma-assisted molecular beam epitaxy.

4. The fabrication of M-plane gallium nitride as claimed in claim 3, wherein the gallium nitride layer is grown at 500-600° C.

5. The fabrication of M-plane gallium nitride as claimed in claim 4, wherein the gallium nitride layer is grown at 550° C.

6. The fabrication of M-plane gallium nitride as claimed in claim 3, wherein the gallium nitride layer is grown with an N/Ga flux ratio of 40-60.

7. The fabrication of M-plane gallium nitride as claimed in claim 6, wherein the gallium nitride is grown with an N/Ga flux ratio of 53.

8. The fabrication of M-plane gallium nitride as claimed in claim 1, wherein preparing the zinc oxide hexagonal prism includes preparing a base plate and growing the zinc oxide hexagonal prism on a surface of the base plate by hydrothermal reaction.

9. The fabrication of M-plane gallium nitride as claimed in claim 8, wherein the base plate is a Si(100) base plate.

10. The fabrication of M-plane gallium nitride as claimed in claim 8, wherein a reaction solution used in the hydrothermal reaction includes zinc nitrate hexahydrate and hex amethylenetetramine.
